(19) United States
(12) Patent Application Publication
(10) Pub. No.: US 2024/0162308 A1
(43) Pub. Date: May 16, 2024

(54) SEMICONDUCTOR DEVICE AND METHOD FOR MANUFACTURING THEREOF

(71) Applicant: TAIWAN SEMICONDUCTOR MANUFACTURING COMPANY, LTD., Hsinchu (TW)

(72) Inventors: Pin Chun SHEN, Changhua (TW); Che Chia CHANG, Hsinchu (TW); Li-Ying WU, Hsinchu (TW); Jen-Hsiang LU, Taipei (TW); Wen-Chiang HONG, Taipei (TW); Chun-Wing YEUNG, Hsinchu (TW); Ta-Chun LIN, Hsinchu (TW); Chun-Sheng LIANG, Changhua (TW); Shih-Hsun CHANG, Hsinchu (TW); Chih-Hao CHANG, Hsinchu (TW); Yi-Hsien CHEN, Hsinchu (TW)

(21) Appl. No.: 18/107,658

(22) Filed: Feb. 9, 2023

Related U.S. Application Data
(60) Provisional application No. 63/424,255, filed on Nov. 10, 2022.

(51) Int. Cl. H01L 29/417; H01L 29/06; H01L 29/08; H01L 29/40; H01L 29/423; H01L 29/66; H01L 29/775

(52) U.S. Cl. CPC H01L 29/41733; H01L 29/0673; H01L 29/0847; H01L 29/401; H01L 29/42392; H01L 29/66439; H01L 29/66545; H01L 29/775

(57) ABSTRACT

The present disclosure provides a semiconductor structure with having a source/drain feature with a central cavity, and a source/drain contact feature formed in central cavity of the source/drain region, wherein the source/drain contact feature is nearly wrapped around by the source/drain region. The source/drain contact feature may extend to a lower most of a plurality semiconductor layers.

### CROSS-REFERENCE TO RELATED APPLICATIONS

This application claims priority to U.S. Provisional Application Ser. No. 63/424,255 filed Nov. 10, 2022, which is incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. In the course of IC evolution, functional density, i.e., the number of interconnected devices per chip area, has generally increased while geometric size, i.e., the smallest component that can be created using a fabrication process, has decreased. Such advances have increased the complexity of manufacturing and processing ICs; similar developments in IC processing and manufacturing are being developed to meet this progress.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2, 3A-3C, 4A-4C, 5A-5D, 6A-6C, 7A-7C, 8A-8C, 9A-9C, 10A-10C, 11A-11C, 12A-12C, and 13A-13E illustrate various stages of manufacturing a semiconductor device according to embodiments of the present disclosure.

FIGS. 14A-14E illustrate a semiconductor device according to embodiments of the present disclosure.

FIGS. 15A-15C, 16A-16C, and 17A-17C illustrate a semiconductor device according to embodiments of the present disclosure.

FIGS. 18, 19A-19C, 20A-20C, 21A-21C, 22A-22C, 23A-23C, and 24A-24C schematically illustrate various stages of manufacturing a semiconductor device according to embodiments of the present disclosure.

FIGS. 25A-25B, and 26 are cross-sectional views of simulation forksheet structure according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context.

The present disclosure provides a semiconductor structure with having a source/drain contact feature formed in an interior portion of a source/drain region, wherein the source/drain contact feature is nearly wrapped around by the source/drain region. In some embodiments, source/drain regions are formed in a reduced size with a sacrificial epitaxial feature formed in a central portion. The sacrificial epitaxial feature is eventually removed and replaced by the source/drain contact feature.

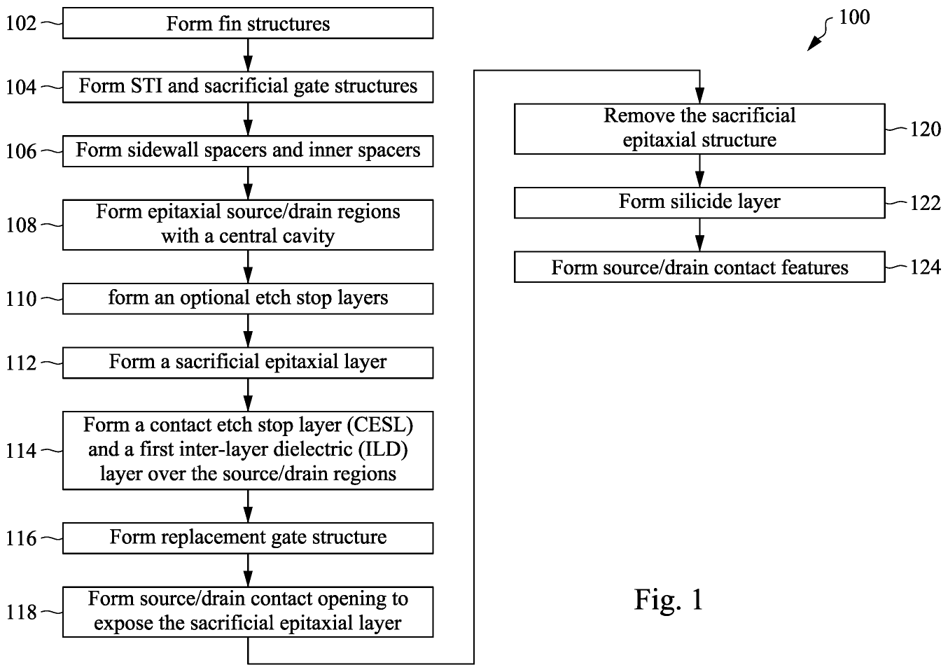

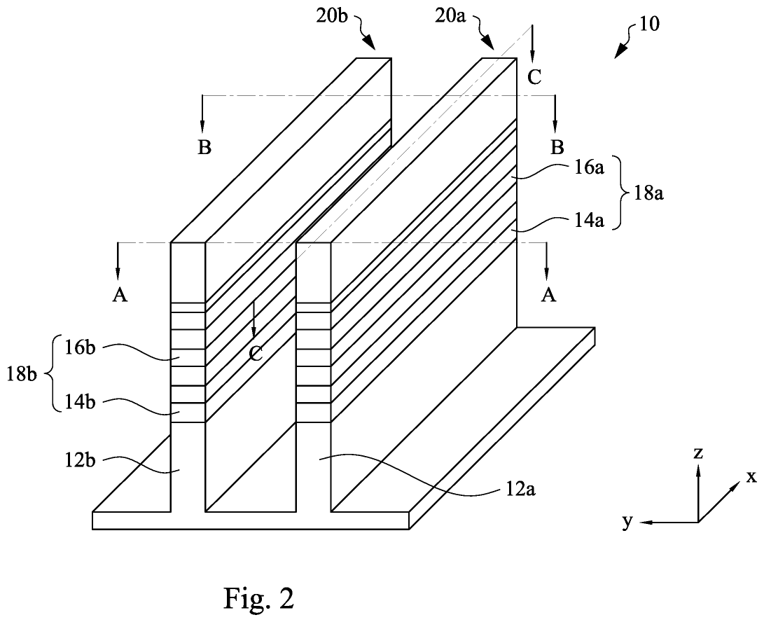

FIG. 1 is a flow chart of a method 100 for manufacturing of a semiconductor device according to embodiments of the present disclosure. FIGS. 2, 3A-3C, 4A-4C, 5A-5C, 6A-6C, 7A-7C, 8A-8C, 9A-9C, 10A-10C, 11A-11C, 12A-12C, and 13A-13E illustrate various stages of manufacturing a semiconductor device 10 according to the method 100.

The method 100 begins at operation 102 where semiconductor fins 20a, 20b are formed over a substrate 12, as shown in FIG. 2. FIG. 2 is a schematic perspective view of the semiconductor device 10. The substrate 12 is provided to form the semiconductor device 10 thereon. The substrate 12 may include a single crystalline semiconductor material such as, but not limited to Si, Ge, SiGe, GaAs, InSb, GaP, GaSb, InAlAs, InGaAs, GaSbP, GaAsSb, and InP. The substrate 12 may include various doping configurations depending on circuit design. For example, different doping profiles, e.g., n-wells, p-wells, may be formed in the substrate 12 in regions designed for different device types, such as n-type field effect transistors (nFET), and p-type field effect transistors (pFET). In some embodiments, the substrate 12 may be a silicon-on-insulator (SOI) substrate including an insulator structure (not shown) for enhancement.

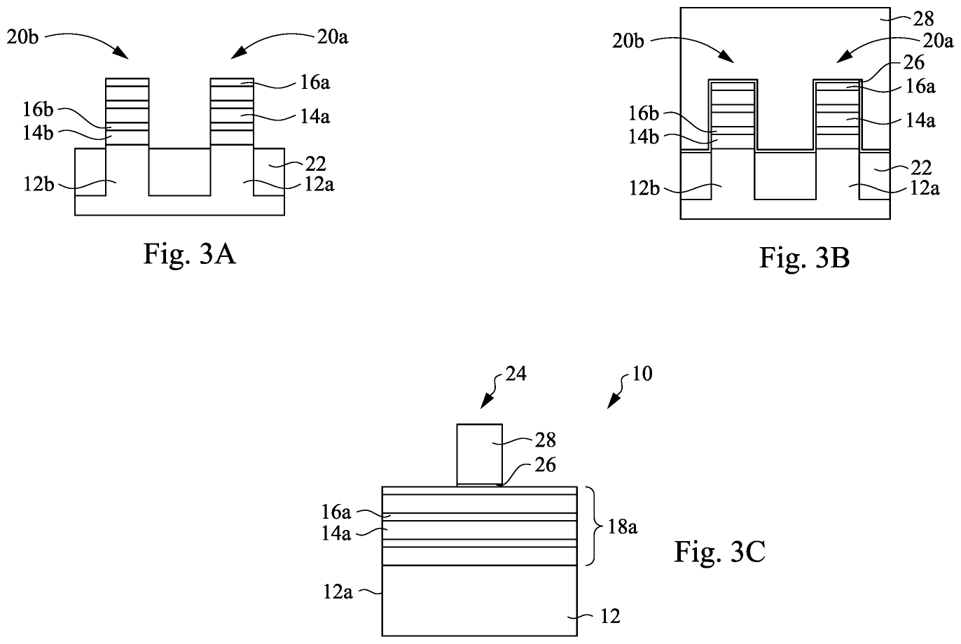

In the embodiment shown in FIG. 2, the substrate 12 includes a p-doped region or p-well 12b and an n-doped region or n-well 12a. One or more n-type devices, such as nFETs, are to be formed over and/or within p-well 12b. One or more p-type devices, such as pFETs, are to be formed over and/or within n-well 12a. FIG. 3 shows that the p-well 12b is in a doped local region of a doped substrate, which is not limiting. In other embodiments, the p-well 12b and the n-well 12a may be separated by one or more insulation bodies, e.g., shallow trench insulation (“STI”).

A semiconductor stack 18a may be formed over the n-well 12a and patterned to form the semiconductor fin 20a. The semiconductor stack 18a includes alternating semiconductor layers made of different materials to facilitate formation of nanosheet channels in a multi-gate n-type device, such as nanosheet channel pFETs. In some embodiments, the semiconductor stack 18a includes first semiconductor layers 14a interposed by second semiconductor layers 16a. The first semiconductor layers 14a and second semiconductor layers 16a have different compositions. In some embodiments, the two semiconductor layers 14a and 16a provide for different oxidation rates and/or different etch selectivity. In later fabrication stages, portions of the second semiconductor layers 16a form nanosheet channels in a multi-gate device. Three first semiconductor layers 14a and three second semiconductor layers 16a are alternately arranged as illustrated in FIG. 3 as an example. More or less semiconductor layers 14a and 16a may be included in the semiconductor stack 18a depending on the desired number of channels in the semiconductor device to be formed. In some embodiments, the number of semiconductor layers 14a and 16a is between 1 and 10. As discussed below, embodiments of the present disclosure increase the number of semiconductor layers in the semiconductor device 10 because shape of the epitaxial source/drain features and the source/drain contact.

In some embodiments, the first semiconductor layer 14a may include silicon germanium (SiGe). The first semiconductor layer 14a may be a SiGe layer including more than 25% Ge in molar ratio. For example, the first semiconductor layer 14a may be a SiGe layer including Ge in a molar ration in a range between 25% and 50%. In some embodiments, the first semiconductor layer 14a and the first semiconductor layer 14? have substantially the same composition. The second semiconductor layer 16a may include silicon, Ge, a compound semiconductor such as SiC, GeAs, GaP, InP, InAs, and/or InSb, an alloy semiconductor such as SiGe, GaAsP, AllnAs, AlGaAs, InGaAs, GaInP, and/or GaInAsP, or combinations thereof. In some embodiments, the second semiconductor layer 16a may be a Ge layer. The second semiconductor layer 16a may include p-type dopants, boron etc.

A semiconductor stack 18b may be formed over the p-well 12b and then patterned to form the semiconductor fin 20b. The semiconductor stack 18b includes alternating semiconductor layers made of different materials to facilitate formation of nanosheet channels in a multi-gate n-type device, such as nanosheet channel nFETs. In some embodiments, the semiconductor stack 18b includes third semiconductor layers 14b interposed by fourth semiconductor layers 16b. The third semiconductor layers 14b and fourth semiconductor layers 16b have different compositions. In some embodiments, the two semiconductor layers 14b and 16b provide for different oxidation rates and/or different etch selectivity. In later fabrication stages, portions of the fourth semiconductor layers 16b form nanosheet channels in a multi-gate device. Three third semiconductor layers 14b and three fourth semiconductor layers 16b are alternately arranged as illustrated in FIG. 3 as an example. More or less semiconductor layers 14b and 16b may be included in the semiconductor stack 18b depending on the desired number of channels in the semiconductor device to be formed. In some embodiments, the number of semiconductor layers 14b and 16b is between 1 and 10.

In some embodiments, the third semiconductor layer 14b may include silicon germanium (SiGe). The third semiconductor layer 14b may be a SiGe layer including more than 25% Ge in molar ratio. For example, the third semiconductor layer 14b may be a SiGe layer including Ge in a molar ration in a range between 25% and 50%. The fourth semiconductor layer 16b may include silicon (Si). In some embodiments, the fourth semiconductor layer 16b may include n-type dopants, such as phosphorus (P), arsenic (As), etc.

The semiconductor layers 14a, 14b, 16a, 16b may be formed by a molecular beam epitaxy (MBE) process, a metalorganic chemical vapor deposition (MOCVD) process, and/or other suitable epitaxial growth processes.

In some embodiments, each semiconductor layer 16a, 16b has a thickness in a range between about 5 nm and about 30 nm. In other embodiments, each second semiconductor layer 16a, 16b has a thickness in a range between about 10 nm and about 20 nm. In some embodiments, each semiconductor layer 16a, 16b has a thickness in a range between about 6 nm and about 12 nm. In some embodiments, the semiconductor layers 16a in the semiconductor stack 18a and the semiconductor layers 16b in the semiconductor stack 18b are uniform in thickness.

The semiconductor layers 14a, 14b may eventually be removed and serve to define a vertical distance between adjacent channel regions for a subsequently formed multi-gate device. In some embodiments, the thickness of the semiconductor layer 14a, 14b is equal to or greater than the thickness of the semiconductor layer 16a, 16b. In some embodiments, each semiconductor layer 14a, 14b has a thickness in a range between about 5 nm and about 50 nm. In other embodiments, each semiconductor layer 14a, 14b has a thickness in a range between about 10 nm and about 30 nm.

The semiconductor stacks 18a, 18b may be formed separately. For example, the semiconductor stack 18a is first formed over the entire substrate, i.e. over both the n-well 12a and the p-well 12b then recesses are formed in the semiconductor stacks 18a in areas over the p-well 12b to expose the p-well 12b, and the semiconductor stack 18b is then formed in the recesses over the p-well 12b while the semiconductor stack 18a is covered by a mask layer.

The semiconductor fins 20a, 20b are formed from the semiconductor stacks 18a, 18b and a portion of the n-well 12a, the p-well 12b underneath respectively. Each semiconductor fin 20a, 20b has an active portion formed from the semiconductor stacks 18a, 18b, and a well portion formed in the n-well 12a, the p-well 12b, respectively.

In operation 104, a shallow trench isolation (STI) layer and sacrificial gate structure are formed, as shown in FIGS. 3A-3C. FIG. 3A is a schematic cross sectional view along the A-A line in FIG. 2. FIG. 3B is a schematic cross sectional view along the B-B line in FIG. 2. FIG. 3C is a schematic cross sectional view along the C-C line in FIG. 2. An isolation material is filled in the trenches between the semiconductor fins 20a, 20b and then etched back to below the semiconductor stacks 18a, 18b of the semiconductor fins 20a, 20b. The isolation material is deposited over the substrate 12 to cover at least a part of the well portions of the semiconductor fins 20a, 20b. The isolation material may be formed by a high density plasma chemical vapor deposition (HDP-CVD), a flowable CVD (FCVD), or other suitable deposition process. In some embodiments, the isolation material may include silicon oxide, silicon nitride, silicon oxynitride, fluorine-doped silicate glass (FSG), a low-k dielectric, combinations thereof. In some embodiments, the isolation material is formed to cover the semiconductor fins 20a, 20b by a suitable deposition process to fill the trenches between the semiconductor fins 20a, 20b, and then recess etched using a suitable anisotropic etching process to expose the active portions of the semiconductor fins 20a, 20b resulting in the isolation layer 22.

A sacrificial gate dielectric layer 26 may be formed conformally over the semiconductor fins 20a, 20b, and the isolation layer 22. In some embodiments, the sacrificial gate dielectric layer 26 may be deposited by a CVD process, a sub-atmospheric CVD (SACVD) process, a FCVD process, an ALD process, a PVD process, or other suitable process. The sacrificial gate dielectric layer 26 may include one or more layers of dielectric material, such as SiO₂, SiN, a high-k dielectric material, and/or other suitable dielectric material.

A sacrificial gate electrode layer 28 is deposited over the exposed surfaces of the semiconductor device 10. The sacrificial gate electrode layer 28 may be blanket deposited on the over the sacrificial gate dielectric layer 26. The sacrificial gate electrode layer 28 includes silicon such as polycrystalline silicon or amorphous silicon. The thickness of the sacrificial gate electrode layer is in a range between about 42 nm and about 200 nm. In some embodiments, the sacrificial gate electrode layer 28 is subjected to a planarization operation. The sacrificial gate electrode layer 28 may be deposited using CVD, including LPCVD and PECVD, PVD, ALD, or other suitable process.

The sacrificial gate structures 24 are formed over the isolation layer 22 and over the exposed portions of the semiconductor fins 20a, 20b. The sacrificial gate structures 24 are formed over portions of the semiconductor fins 20a, 20b which are to be channel regions. The sacrificial gate structures 24 may be formed by patterning the sacrificial gate dielectric layer 26 and the sacrificial gate electrode layer 28.

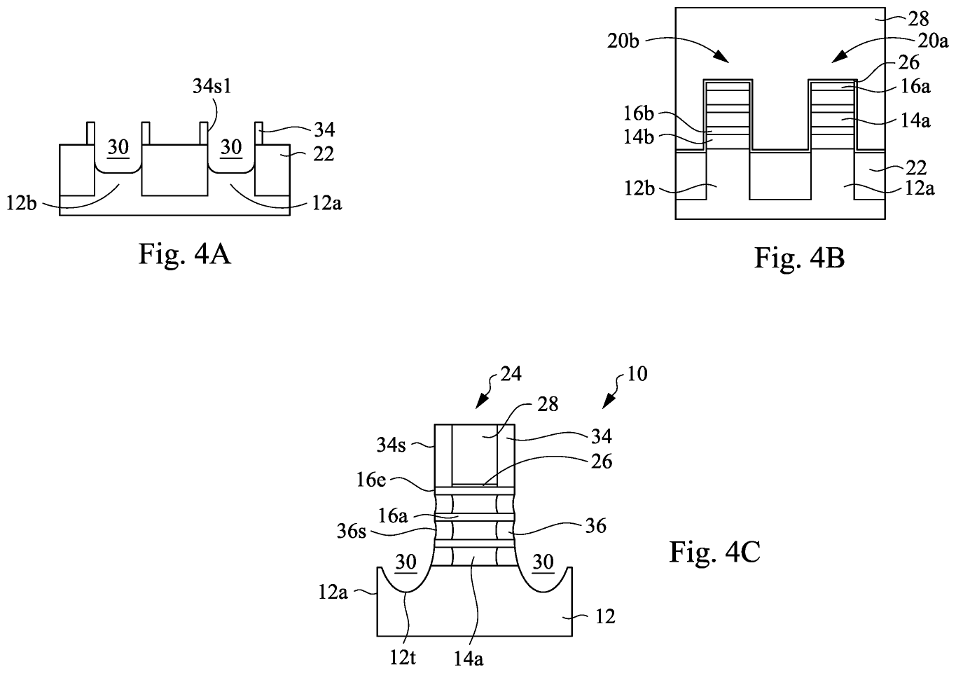

In operation 106, sidewall spacers 34 and inner spacers 36 are formed as shown in FIGS. 4A-4C. FIG. 4A is a schematic perspective cross sectional view along the A-A line in FIG. 2. FIG. 4B is a schematic cross sectional view along the B-B line in FIG. 2. FIG. 4C is a schematic cross sectional view along the C-C line in FIG. 2.

The sidewall spacers 34 are formed on sidewalls of the sacrificial gate structures. After the sacrificial gate structures 24 are formed, the sidewall spacers 34 are formed by a blanket deposition of an insulating material followed by anisotropic etch to remove insulating material from horizontal surfaces. The sidewall spacers 34 may have a thickness in a range between about 4 nm and about 7 nm. In some embodiments, the insulating material of the sidewall spacers 34 is a silicon nitride-based material, such as SiN, SiON, SiOCN or SiCN and combinations thereof.

The exposed semiconductor fins 20a, 20b are etched and the inner spacers 36 are formed. Even though described together in each operation, processes for regions for p-type devices, i.e. over the n-well 12a, and for n-type devices, i.e. over the p-well 12b, may be performed separately using patterned masks and different processing recipes.

The semiconductor fins 20a, 20b not covered by the sacrificial gate structures 24 are etched to expose well portions of the semiconductor fins 20a, 20b and form source/drain openings 30, in which source/drain regions are subsequently formed. In some embodiments, suitable dry etching and/or wet etching may be used to remove the semiconductor layers 14a, 14b, 16a, 16b, together or separately.

After recess etch of the semiconductor fins 20a, 20b, the inner spacers 36 are formed. To form the inner spacers 36, the semiconductor layers 14a, 14b under the sidewall spacers 34 are selectively etched from the semiconductor layers 16a, 16b along the horizontal direction, or x-direction, to form spacer cavities. In some embodiments, the semiconductor layers 14a, 14b can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, an etching thickness of the semiconductor layers 14a, 14b is in a range between about 2 nm and about 10 nm along the X direction.

After forming the spacer cavities, the inner spacers 36 are formed in the spacer cavities by conformally deposit and then partially remove an insulating layer. The insulating layer can be formed by ALD or any other suitable method. The subsequent etch process removes most of the insulating layer except inside the cavities, resulting in the inner spacers 36. The inner spacers 36 have a thickness along the X direction in a range from about 4 nm to about 7 nm.

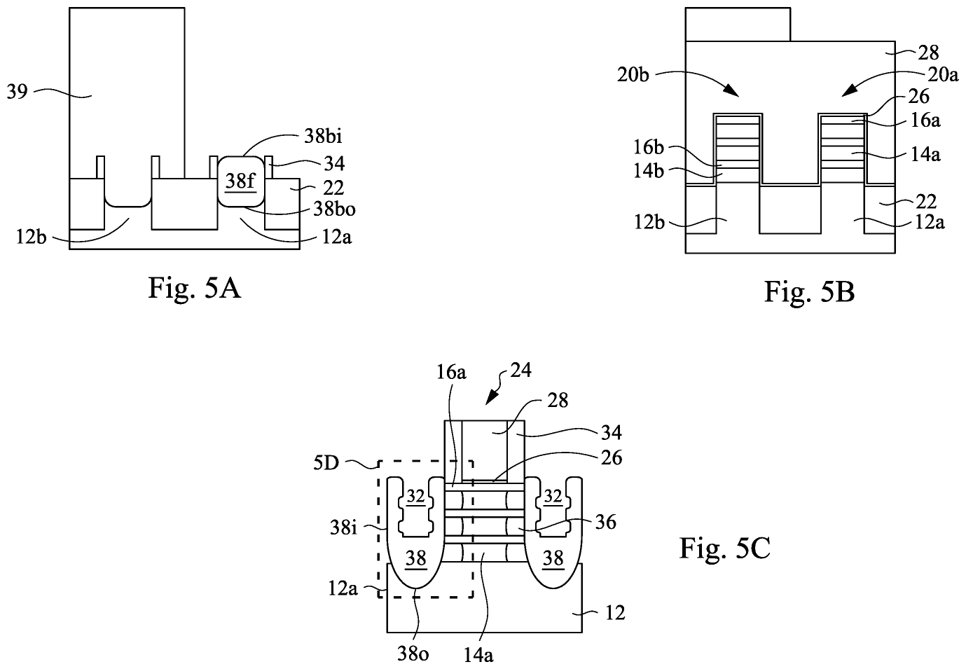

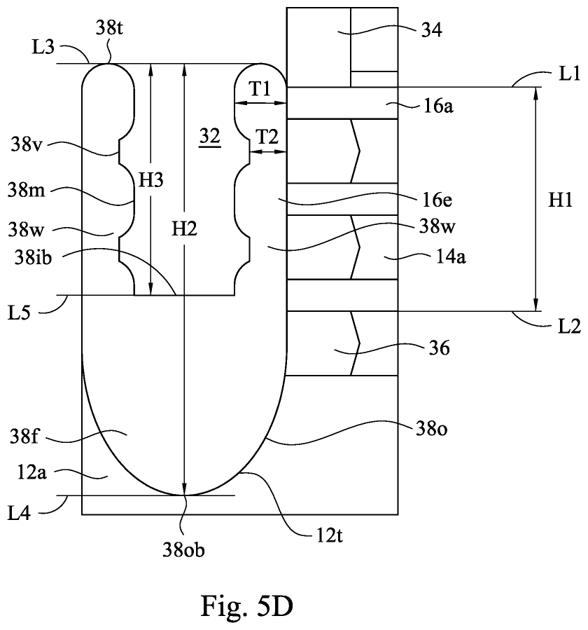

In operation 108, epitaxial source/drain regions 38 formed, as shown in FIGS. 5A-5D. FIG. 5A is a schematic perspective cross sectional view along the A-A line in FIG. 2. FIG. 5B is a schematic cross sectional view along the B-B line in FIG. 2. FIG. 5C is a schematic cross sectional view along the C-C line in FIG. 2. FIG. 5D is a partial enlarged view of the semiconductor device 10 in the area 5D in FIG. 5C. The epitaxial source/drain regions 38 for the p-type devices may be formed while the n-type device area is covered by a mask 39, which may include a hard mark layer and a photoresist layer.

The epitaxial source/drain regions 38 are grown the source/drain opening 30 from exposed semiconductor surfaces. After formation of the inner spacers 36, end surfaces 16e of the semiconductor layers 16a, a top surface 12t of the n-well 12a of the substrate 12, side surface 34s of the sidewall spacers 34, and side surfaces 36s of the inner spacers 35 are exposed to the source/drain openings 30.

The epitaxial source/drain regions 38 may be formed by any suitable method, such as by CVD, CVD epitaxy, molecular beam epitaxy (MBE), or any suitable deposition technique. The epitaxial source/drain regions 38 for the p-type devices may include one or more layers of Si, SiGe, Ge with p-type dopants, such as boron (B), for a p-type device, such as pFET. In some embodiments, the epitaxial source/drain regions 38 may be SiGeB material, wherein boron is a dopant. The dopant concentration in the epitaxial source/drain regions 38 include a dopant concentration of between about 1E20 atom s/cm3 and about 5E21 atoms/cm3.

In operation 108, the epitaxial source/drain regions 38 are grown from the end surfaces 16e and the top surfaces 12t within the source/drain opening 30. Conventionally, epitaxial source/drain regions fill up the source/drain openings 30. Unlike conventional technology, the epitaxial source/drain region 38 according to embodiments of the present disclosure only occupies an outer portion of the source/drain opening 30. For example, the epitaxial source/drain region 38 is substantially hollow having a central cavity 32. The central cavity 32 provides additional contact areas between source/drain contacts to be formed and the source/drain region 38. Not meant to be bound by theory, conventionally, the source/drain regions fill up the source/drain openings to maximize the volume, thus, maximal strength. However, as the device dimension reduces, adequate strength for source/drain regions also reduces and may be achieved with smaller volume.

In some embodiments, the epitaxial source/drain regions 38 may be grown in an epitaxial chamber by cyclically performing a deposition followed by an etch process. Process parameters, such as temperature, pressure, precursor ratio, flow rate, duration, may be adjusted to obtain a desirable profile. In some embodiments, the epitaxial source/drain regions 38 may be grown in a substantially conformal manor from the semiconductor surfaces, i.e. the end surfaces 16e and the top surface 12t. Because the end surfaces 16e and the top surface 12t are not connected, the epitaxial source/drain region 38 may start from discrete crystalline “islands”. In some embodiments, growth of the source/drain region 38 may terminate after the discrete crystalline “islands” are connected forming one unitary crystalline structure. In some embodiments, the growth of the source/drain region 38 may terminate after the discrete crystalline “islands” are connected forming one unitary crystalline structure and the source/drain region 38 near the end surfaces 16e reaches a target thickness.

FIGS. 5A, 5C and 5D schematically illustrate the shape of the epitaxial source/drain region 38 according to some embodiments of the present disclosure. The source/drain region 38 may include a fin portion 38f and one or two wing portion 38w. The fin portion 38f is grown from the n-well 12a and between the isolation layer 22. The wing portions 38w are grown from the semiconductor layers 16a. In FIGS. 5C, each of the source/drain regions 38 are formed between two sacrificial gate structures 24, therefore, has two wing portions 38w even though only one sacrificial gate structure 24 is shown. The fin portion 38f and the wing portions 38w are connected to form a unitary body. In the cross section of FIG. 5C, the epitaxial source/drain region 38 has an outer profile 38o and an inner profile 38i. The outer profile 38o is defined by the shape of the source/drain opening 30. Because the source/drain region 38 includes multiple discrete crystalline islands, the inner profile 38i may include multiple crystalline facets from the multiple discrete islands. In some embodiments, the inner profile 38i is a distinct concave profile having one or more “kinks” defined by valley sections 38v and mountain sections 38m. The mountain sections 38m correspond to the end surfaces 16e of the semiconductor layers where the source/drain region 38 has a thicker thickness T1. The valley sections 38v correspond to the inner spacers 36 where the source/drain region 38 has a thinner thickness T2. In some embodiments, the thickness T1 may be in a range between about 2 nm and 10 nm, and the thickness T2 may be in a range between about 1 nm to 5 nm.

As shown in FIG. 5D, a top surface of the topmost semiconductor layer 16a is located at a first vertical level L1, a bottom surface of the lower most semiconductor layers 16a is located at a second vertical level L2. Height H1 denotes the difference between the vertical level L1 and the vertical level L2. The height H1 may be referred to as the channel stack height. A top surface 38t is located at a vertical level L3. A bottom surface 38ob is located at a vertical level L4. The height H2 denotes the difference between the vertical level L3 and the vertical level L4. The height H2 may be referred to as source/drain region height. A bottom 38ib of the central cavity 32 is located that a vertical level L5. The height H3 denotes the difference between the vertical level L3 and the vertical level L5. The height H3 may be referred to as the cavity height. In some embodiments, the third vertical level L3 is higher the first vertical level L1. The fourth vertical level L4 is lower than the second vertical level L2 so that the source/drain region 38 covers all the semiconductor layers 16a. The fifth vertical level L5 is lower than the first vertical level L1. In some embodiments, the fifth vertical level L5 may be lower than the second level L2. For example, the fifth vertical level L5 is between the second level L2 and the fourth level L4. In some embodiments, the fifth vertical level L5 is substantially level with the second vertical level L2.

The outer profile 38o and the inner profile 38i join at the top surface 38t. The outer profile 38o extends from the top surface 38t to the bottom surface 38ob. The inner profile extends from the top surface 38t to the bottom surface 38ib at the central cavity 32. The fin portion 38f extend from the cavity bottom 38bi and the bottom surface 38b. The wing portions 38w extend from the top surface 38t to the cavity bottom 38bi.

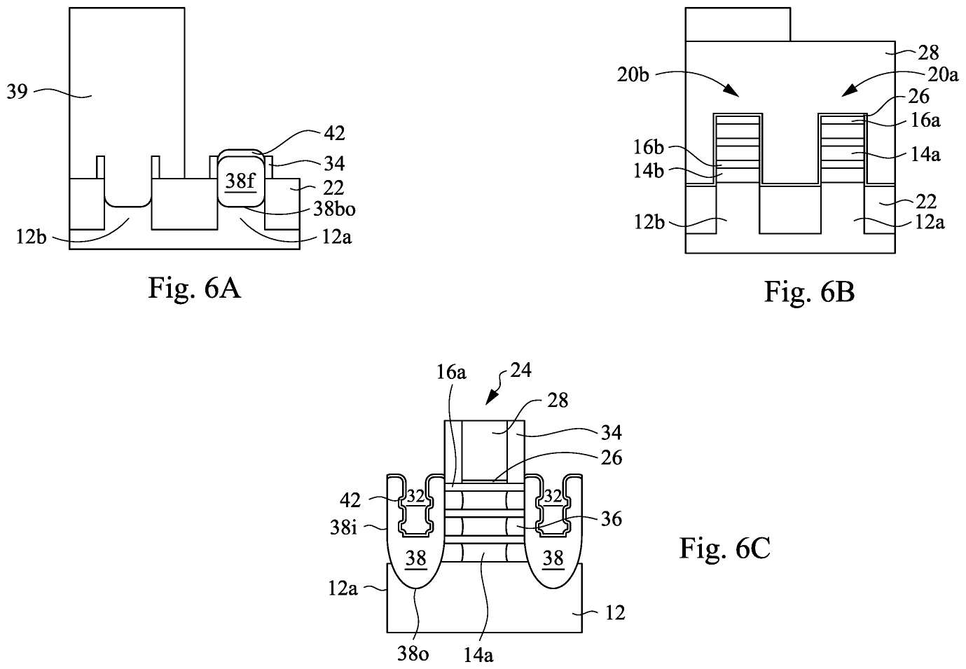

In operation 110, an optional etch stop layer 42 is formed over the source/drain region 38, as shown in FIGS. 6A-6C. FIG. 6A is a schematic perspective cross sectional view along the A-A line in FIG. 2. FIG. 6B is a schematic cross sectional view along the B-B line in FIG. 2. FIG. 6C is a schematic cross sectional view along the C-C line in FIG. 2.

The etch stop layer 42 may be formed from a material having an etch selectivity relative to the subsequently formed sacrificial layer, and may function as an etch stop layer to protect the epitaxial source/drain region 38. In some embodiment, the etch stop layer 42 may be a semiconductor layer selectively formed on the semiconductor surfaces, such as the top surface 38t and the inner profile 38i of the epitaxial source/drain region 38. In some embodiment, the etch stop layer 42 may be a semiconductor layer, such as a silicon containing layer, and may be used to form a silicide layer over the source/drain region 38. In some embodiment, the etch stop layer 42 may be an epitaxial layer formed in the same chamber as the source/drain region 38.

In some embodiments, the epitaxial source/drain regions 38 for the p-type devices may include SiGe layer and the etch stop layer 42 may include a SiGe layer with a lower Ge concentration than the epitaxial source/drain region 38. For example, the etch stop layer 42 may be a SiGe layer having a Ge concentration of less than 40%. In some embodiments, the etch stop layer 42 may be a polycrystalline SiGe or an amorphous SiGe layer.

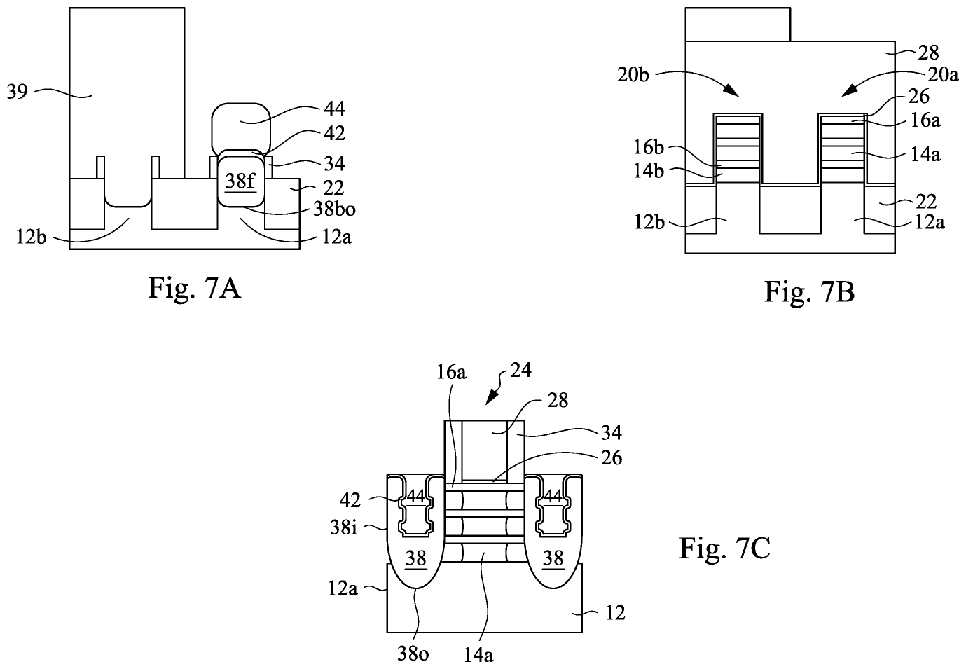

In operation 112, a sacrificial source/drain region 44 is formed to fill the central cavity 32, as shown in FIGS. 7A-7C. FIG. 7A is a schematic perspective cross sectional view along the A-A line in FIG. 2. FIG. 7B is a schematic cross sectional view along the B-B line in FIG. 2. FIG. 7C is a schematic cross sectional view along the C-C line in FIG. 2.

The sacrificial source/drain region 44 may be deposited in the source/drain cavity and cover the source/drain region 38 and the etch stop layer 42 if present. The sacrificial source/drain region 44 may be formed from any suitable material that may be removed from the source/drain region 38 or the etch stop layer 42 if present. In some embodiment, the sacrificial source/drain region 44 may be an epitaxial material formed in the same chamber as the source/drain region 38. In some embodiments, the sacrificial source/drain region 44 may be SiGe, Ge, Al₂O₃, or the like. In some embodiments, the sacrificial source/drain region 44 may be a SiGe layer having a Ge concentration of greater than 60%. In some embodiments, the sacrificial source/drain region 44 may be a Ge layer. In some embodiments, the sacrificial source/drain region 44 may first fill up and then etched back to a level above the first vertical level L1.

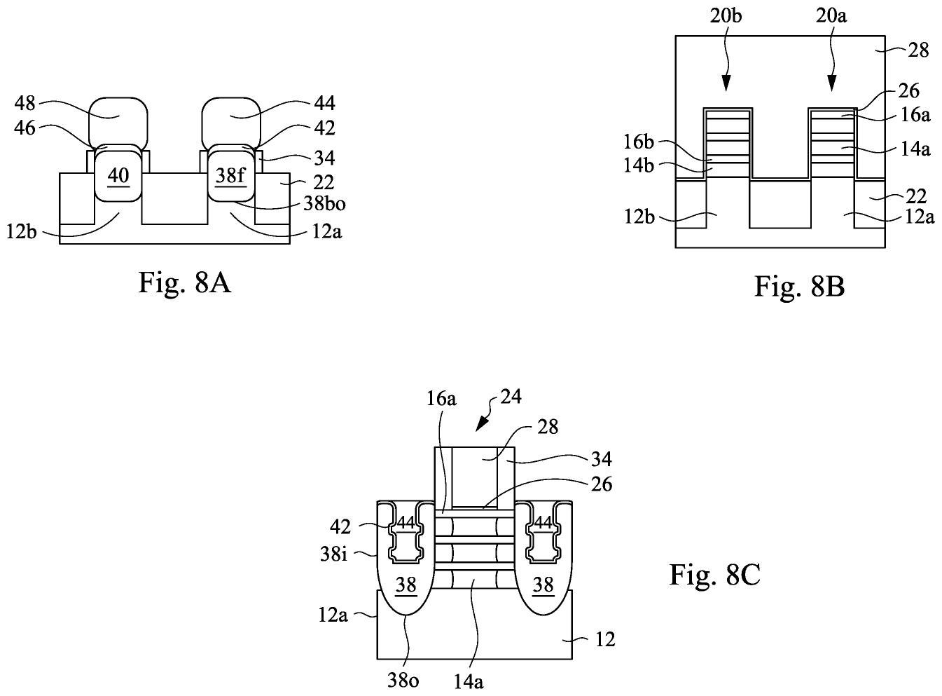

Operations 108, 110, 112 may be repeated on the n-type device areas to form epitaxial source/drain regions 40 for the n-type device, an etch stop layer 46, and a sacrificial source/drain region 48, as shown in FIGS. 8A-8C. FIG. 8A is a schematic perspective cross sectional view along the A-A line in FIG. 2. FIG. 8B is a schematic cross sectional view along the B-B line in FIG. 2. FIG. 8C is a schematic cross sectional view along the C-C line in FIG. 2.

The epitaxial source/drain regions 40 may include one or more layers of Si, SiP, SiC and SiCP. The epitaxial source/drain regions 40 also include n-type dopants, such as phosphorus (P), arsenic (As), etc. In some embodiments, the epitaxial source/drain regions 40 may be a Si layer including phosphorus dopants. Similar to the epitaxial source/drain regions 38, the epitaxial source/drain regions 40 may have a central cavity defined by a distinctive inner profile. In some embodiments, the etch stop layer 46 may include a silicon layer, such as polycrystalline silicon layer or an amorphous silicon layer. In some embodiments, the sacrificial source/drain region 48 may be SiGe, Ge, Al₂O₃, or the like. In some embodiments, the sacrificial source/drain region 48 may be a SiGe layer having a Ge concentration of greater than 60%. In some embodiments, the sacrificial source/drain region 48 may be a Ge layer. In some embodiments, the sacrificial source/drain regions 48 may first fill up and then etched back to cover the epitaxial source/drain regions 40.

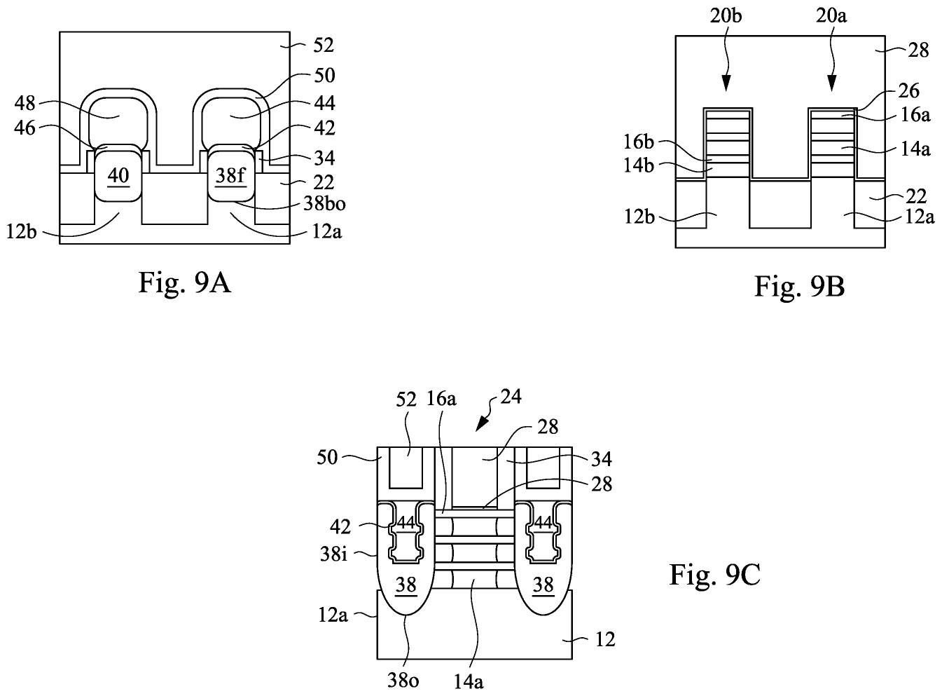

In operation 114, a contact etch stop layer (CESL) 50 and an interlayer dielectric (ILD) layer 52 are formed over the exposed surfaces as shown in FIGS. 9A-9C. FIG. 9A is a schematic cross sectional view along the A-A line in FIG. 2. FIG. 9B is a schematic perspective cross sectional view along the B-B line in FIG. 2. FIG. 9C is a schematic cross sectional view along the C-C line in FIG. 2.

The CESL 50 is formed on the sacrificial source/drain regions 44, 48, the sidewall spacers 34, and the isolation layer 22. In some embodiments, the CESL 50 has a thickness in a range between about 4 nm and about 7 nm. The CESL 50 may include Si₃N₄, SiON, SiCN or any other suitable material, and may be formed by CVD, PVD, or ALD.

The interlayer dielectric (ILD) layer 52 is formed over the CESL 50. The materials for the ILD layer 52 include compounds comprising Si, 0, C, and/or H, such as silicon oxide, SiCOH and SiOC. Organic materials, such as polymers, may be used for the ILD layer 52. The ILD layer 52 protects the epitaxial source/drain regions 38, 40 and the sacrificial source/drain regions 44, 48 during the removal of the sacrificial gate structures 24.

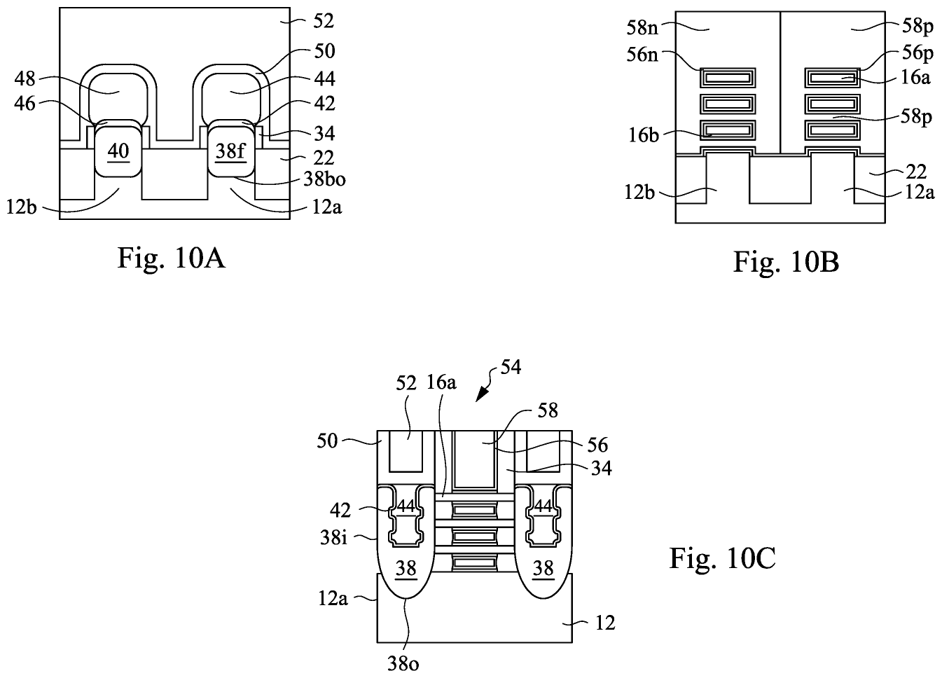

In operation 116, replacement gate structures 54 are formed, as shown in FIGS. 10A-10C. FIG. 10A is a schematic cross sectional view along the A-A line in FIG. 2. FIG. 10B is a schematic perspective cross sectional view along the B-B line in FIG. 2. FIG. 10C is a schematic cross sectional view along the D-D line in FIG. 2.

The sacrificial gate electrode layer 28 and the sacrificial gate dielectric layer 26 are sequentially removed. The sacrificial gate electrode layer 28 can be removed using plasma dry etching and/or wet etching. When the sacrificial gate electrode layer 28 is polysilicon, a wet etchant such as a Tetramethylammonium hydroxide (TMAH) solution can be used to selectively remove the sacrificial gate electrode layer 28 without removing the dielectric materials of the ILD layer 52 and the CESL 50. The sacrificial gate dielectric layer 26 may be removed using a suitable etch process after removal of the sacrificial gate electrode layer. The semiconductor fins 20a, 20b are exposed for subsequent process. The semiconductor layers 14a, 14b are then removed. The semiconductor layers 14a, 14b can be selectively removed using a wet etchant such as, but not limited to, ammonium hydroxide (NH₄OH), tetramethylammonium hydroxide (TMAH), ethylenediamine pyrocatechol (EDP), or potassium hydroxide (KOH) solution. Removal of the semiconductor layers 14a, 14b results in nanosheets of the semiconductor layers 16a, 16b.

The replacement gate structure 54 may include a gate dielectric layer 56, and a gate electrode layer 58. In some embodiments, the replacement gate structure 54 further includes a conductive cap layer. The gate dielectric layer 56 is formed on exposed surfaces after removal of the sacrificial gate structures 24. In some embodiments, the gate dielectric layer 56 may have different composition and dimensions for the n-type devices and p-type devices and are formed separately using patterned mask layers and different deposition recipes. The gate dielectric layer 56 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate dielectric layer 56 may be formed by CVD, ALD or any suitable method. In some embodiments, the thickness of the gate dielectric layer 56 is in a range between about 1 nm and about 6 nm. In some embodiments, an interfacial layer may be formed between the semiconductor layers 16a, 16b and the gate dielectric layer 56. The gate dielectric layer 56 is in contact with the dielectric wall 51.

The gate electrode layer 58 is formed on the gate dielectric layer 56 to fill the gate cavities. The gate electrode layer 58 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, other suitable materials, and/or combinations thereof. In some embodiments, the gate electrode layer 58 may be formed by CVD, ALD, electro-plating, or other suitable method. In some embodiments, a planarization process may be performed after formation of the gate electrode layer 58. In some embodiments, the conductive cap layer may be formed over the gate electrode layer 58. The conductive cap layer may include tungsten.

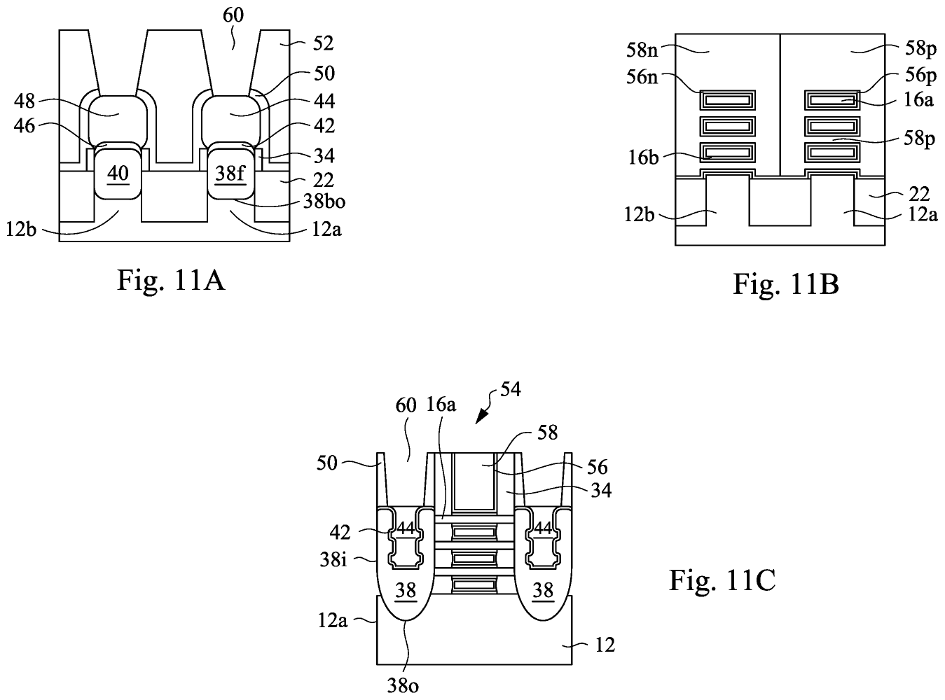

In operation 118, source/drain contact openings 60 are formed through the ILD layer 52 and the CESL 50, as shown in FIGS. 11A-11C. FIG. 11A is a schematic cross sectional view along the A-A line in FIG. 2. FIG. 11B is a schematic perspective cross sectional view along the B-B line in FIG. 2. FIG. 11C is a schematic cross sectional view along the C-C line in FIG. 2. Suitable photolithographic and etching techniques are used to form the contact holes through various layers to expose the sacrificial source/drain regions 44 and 48.

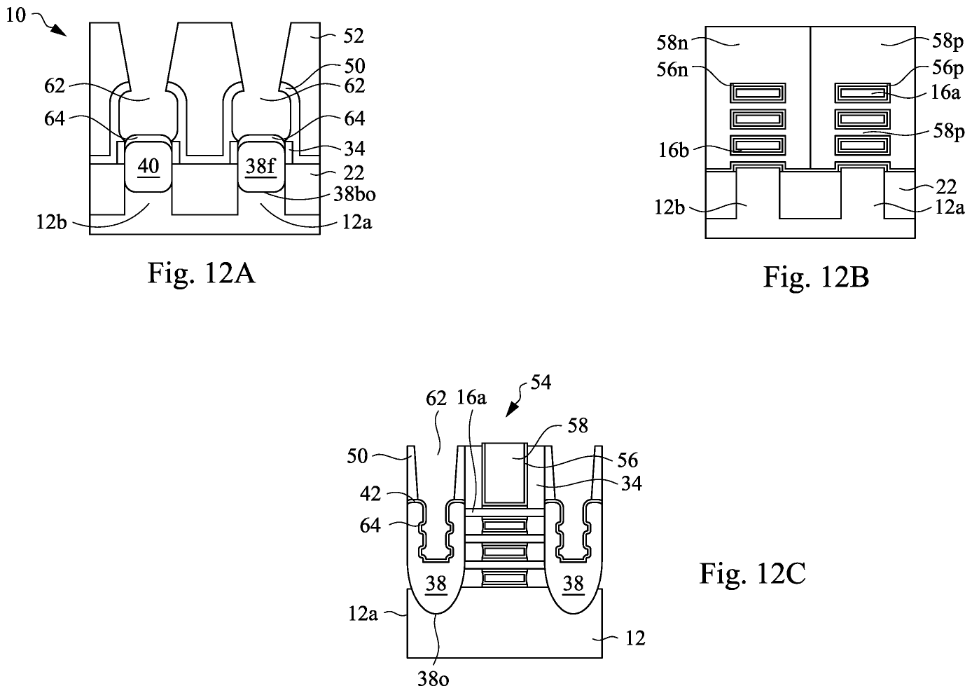

In operation 120, the sacrificial source/drain regions 44 and 48 are removed to form source/drain contact cavities 62, as shown in FIGS. 12A-12C. FIG. 12A is a schematic cross sectional view along the A-A line in FIG. 2. FIG. 12B is a schematic perspective cross sectional view along the B-B line in FIG. 2. FIG. 12C is a schematic cross sectional view along the C-C line in FIG. 2.

A suitable etch process may be performed to remove the sacrificial source/drain regions 44, 48 to expose the source/drain regions 38, 40 or the etch stop layer 42, 46 if present. In some embodiments, the sacrificial source/drain regions 44, 48 may be completely removed using the etch stop layer 42, 46 as an etch stop. In other embodiments, portions of the sacrificial source/drain regions 44, 48 may remain.

In operation 122, a silicide layer 64 is selectively formed over an exposed top surface of the epitaxial source/drain regions 38, 40 exposed by the source/drain contact cavities 62, as shown in FIGS. 12a-12C. In some embodiments, the etch stop layer 42, 46 may be removed prior to forming the silicide layer 64. In other embodiments, a portion of the etch stop layer 42, 46 may be used to form the silicide layer 64.

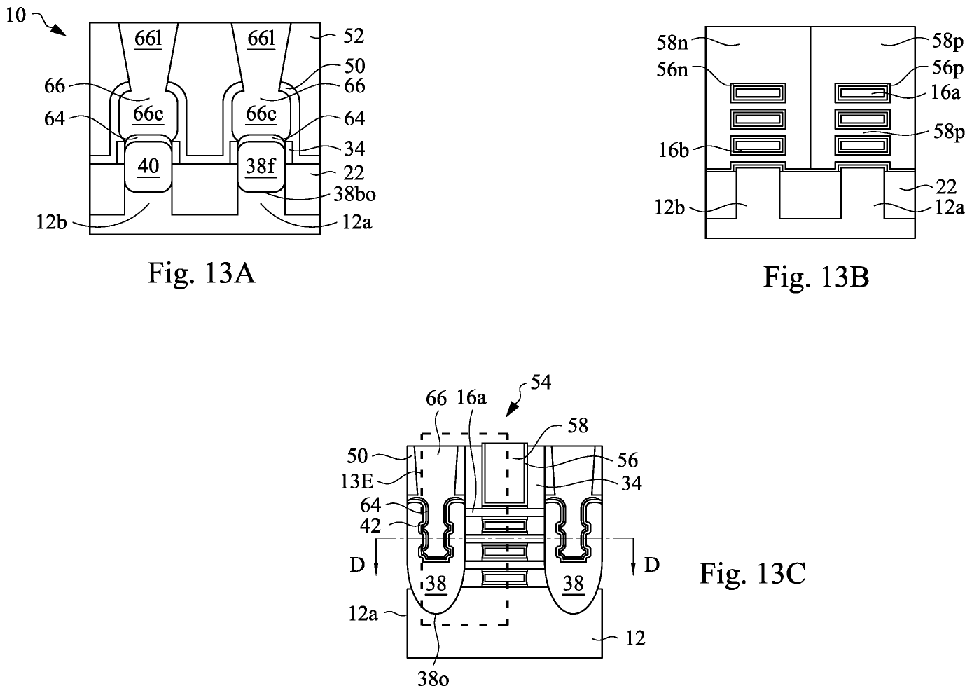

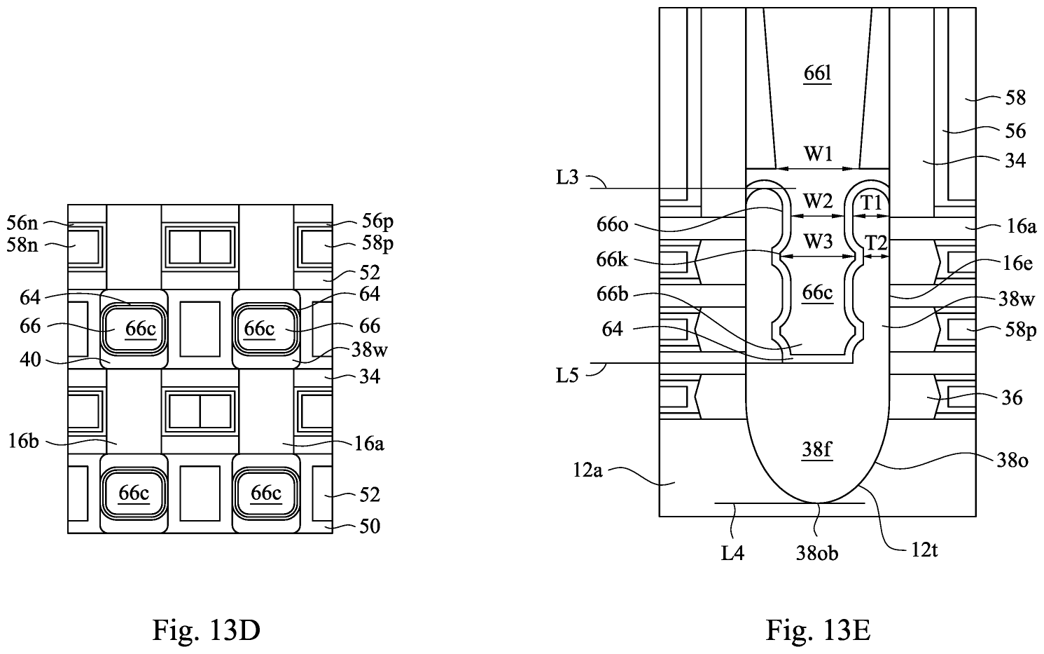

In operation 124, source/drain contact features 66 are then formed by filling the source/drain contact cavities 62 with a conductive material, as shown in FIGS. 13A-13E. FIG. 13A is a schematic cross sectional view along the A-A line in FIG. 2. FIG. 13B is a schematic perspective cross sectional view along the B-B line in FIG. 2. FIG. 13C is a schematic cross sectional view along the C-C line in FIG. 2. FIG. 13D is a schematic cross sectional view along the D-D line in FIG. 13C. FIG. 13E is a partial enlarged view of area 13E in FIG. 13C.

In some embodiments, the conductive material for the source/drain contact features 66 may be formed by CVD, PVD, plating, ALD, or other suitable technique. In some embodiments, the conductive material may include TiN, TaN, Ta, Ti, Hf, Zr, Ni, W, Co, Cu, Ag, Al, Zn, Ca, Au, Mg, Mo, Cr, or the like.

As shown in FIGS. 13E, the source/drain contact features 66 may include an ILD portion 66l disposed in the ILD layer 52 and a core portion 66c extending into the center cavity of the source/drain region 38, 40. The ILD portion 66i is disposed above the first level L1, or above the top surface of the topmost semiconductor layers 16a, 16b. The ILD portion 66i may have a width W1. The core portion 66c may extend from the first vertical level L1 to the fifth vertical level L5. The core portion 66c has an outer profile 66o substantially matches the inner profile 38i of the source/drain region 38. In some embodiments, the outer profile 66o has one or more “kinks” 66k corresponding to the valley sections 38v and mountain sections 38m of the inner profile 38i. The core portion 66c may extend from the first vertical level L1 to the fifth vertical level L5. The core portion 66c has a width W2 at levels corresponding to the semiconductor layers 16a, 16b and a width W3 at levels between the semiconductor layers 16a, 16b. The width W3 is wider than the width W2. Thus, the core portion 66c of the source/drain contact feature 66 have alternative wide and narrow portions. In some embodiments, the width W2 may be in a range between about 8 nm and 12 nm. In some embodiments, the width W3 may be in a range between about 10 nm and 14 nm. As shown in FIG. 13D, the core portion 66c is nearly wrapped around by the wing portion 38w of the source/drain region 38.

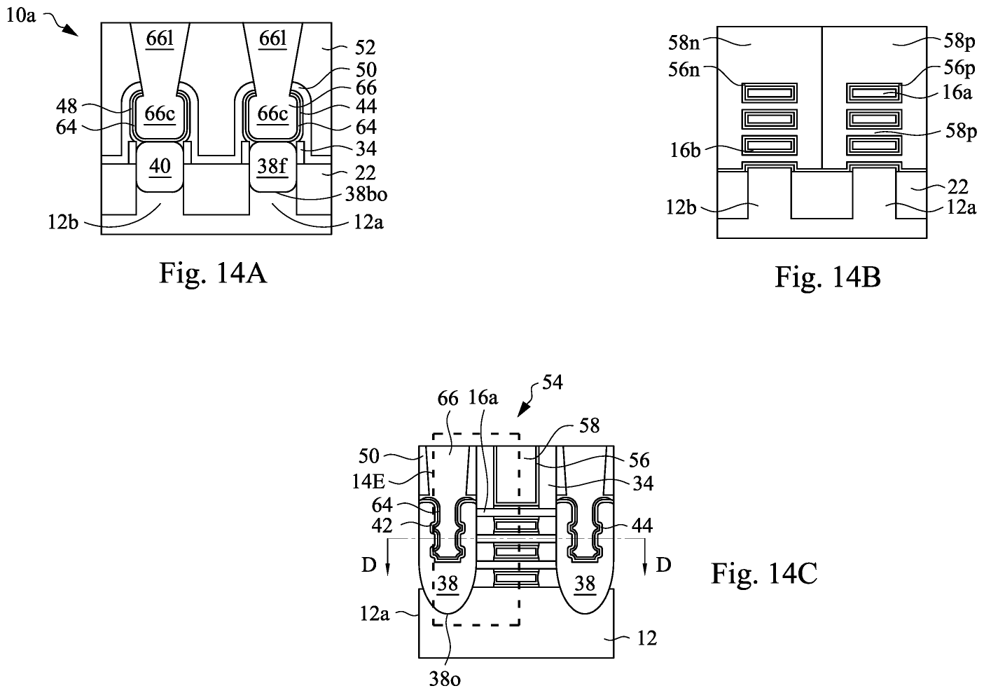

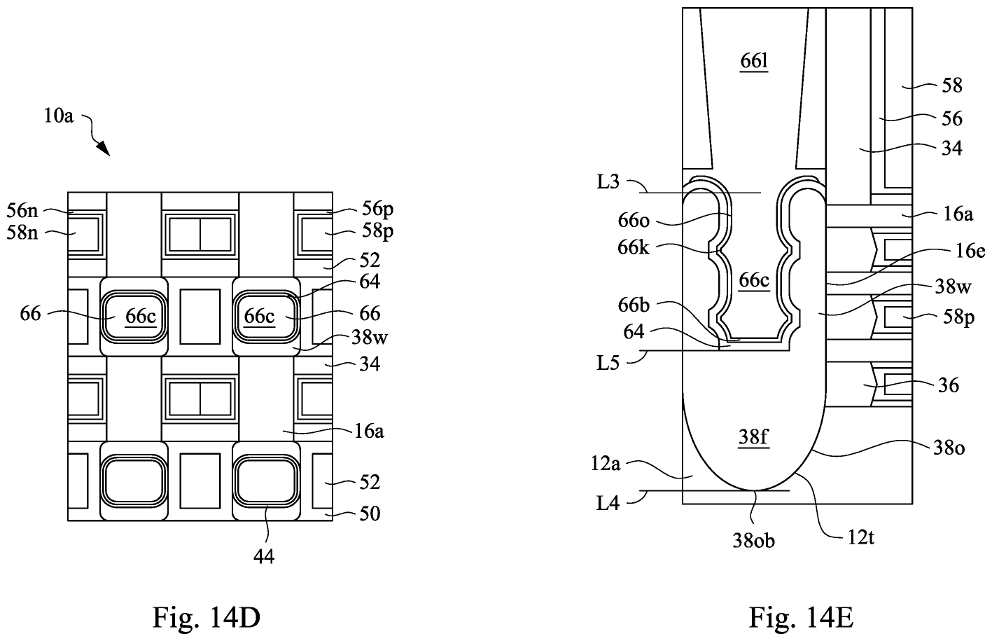

FIGS. 14A-14E illustrate a semiconductor device 10a according to embodiments of the present disclosure. The semiconductor device 10a is substantially similar to the semiconductor device 10 except that the sacrificial source/drain regions 44, 48 only partially removed and remain in the semiconductor device 10a.

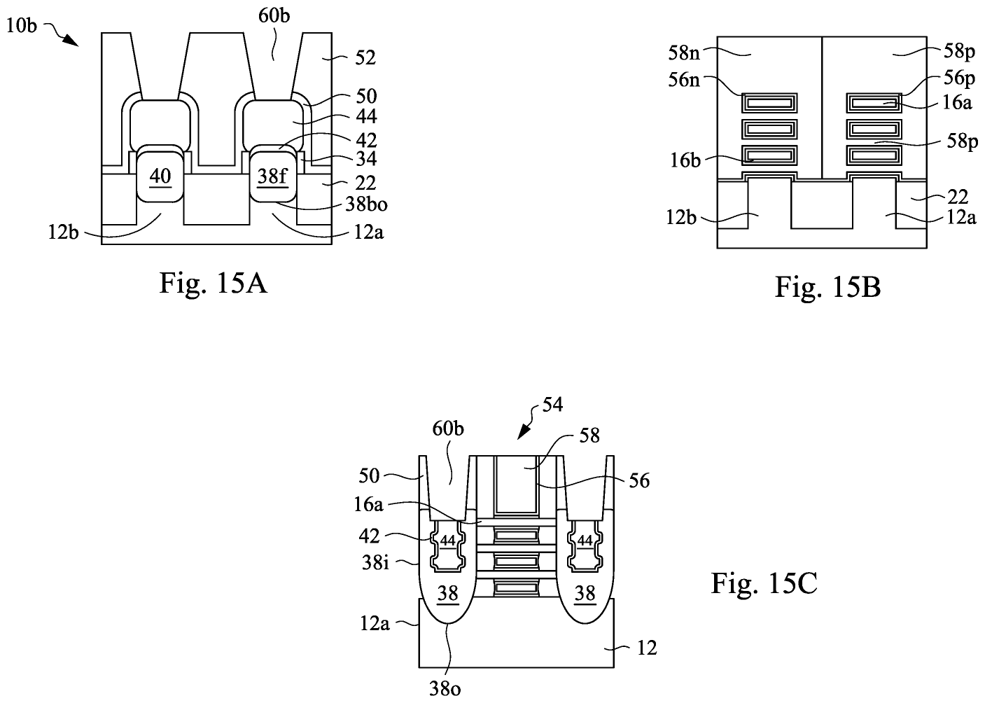

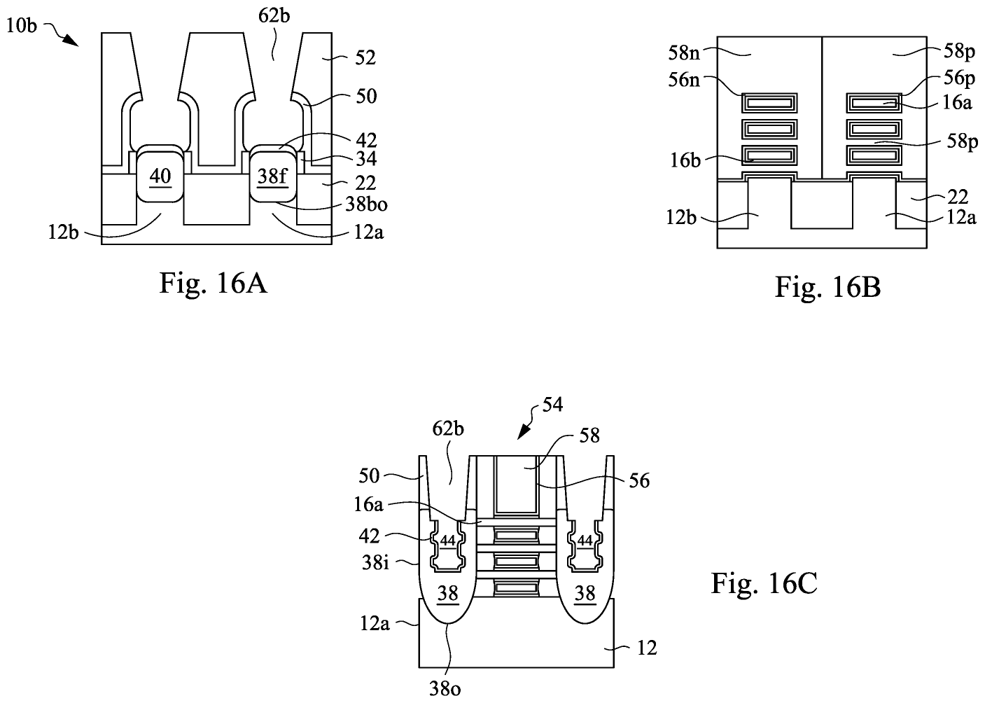

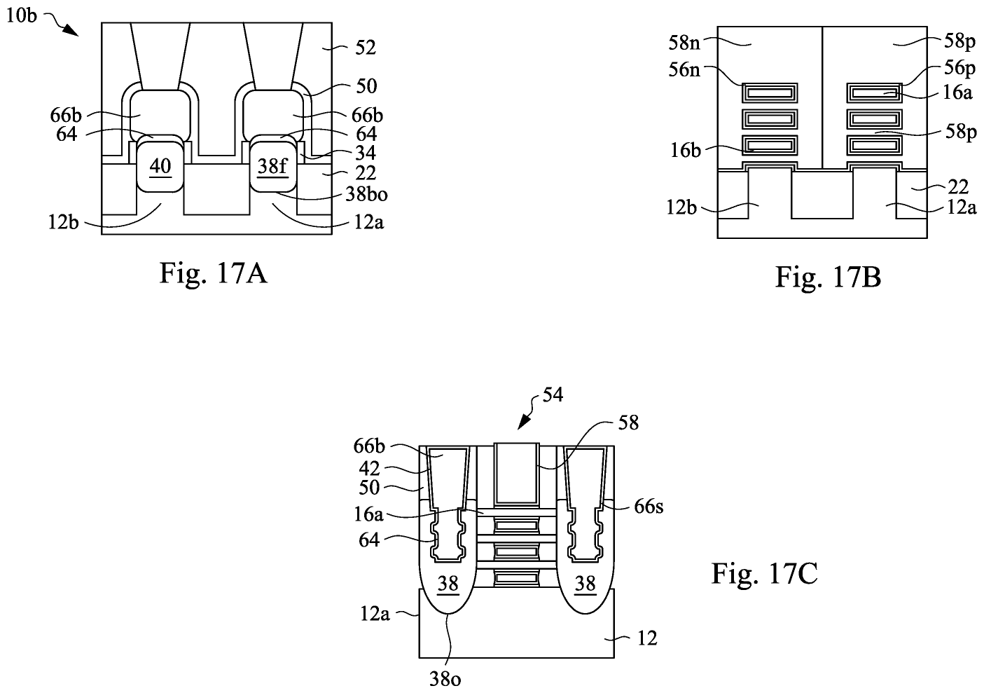

FIGS. 15A-15C, 16A-16C, and 17A-17C illustrate a semiconductor device 10b according to embodiments of the present disclosure. The semiconductor device 10 is similar to semiconductor device 10 except that, in operation 118, source/drain contact openings 60b is formed by removing a portion of the source/drain region 38, 40, as shown in FIGS. 15A-15C. The source/drain contact openings 60b expose both the sacrificial source/drain regions 44/48 and the source/drain regions 38, 40. In operation 120, the sacrificial source/drain region 44/48 are removed as shown in FIGS. 16A-16C. Contact cavities 62b formed in the operation 120 has a shoulder in the source/drain regions 38/40. In operation 124, source/drain contact features 66b includes a shoulder 66s below the top surface 38t of the source/drain region 38, as shown in FIG. 17A-17C.

The source/drain contacts and the source/drain region are in contact along the inner profiles 38i of the source/drain regions 38. The mountain sections and valley sections improve contact area and increase reach of the source/drain contact. The source/drain region according to the present disclosure may also be used in forksheet structure to mitigate wall loss impact in the forksheet. FIGS. 18, 19A-19C, 20A-20C, 21A-21C, 22A-12C, 23A-23C, and 24A-24C schematically illustrate a semiconductor device 200 with forksheet structures according to embodiments of the present disclosure.

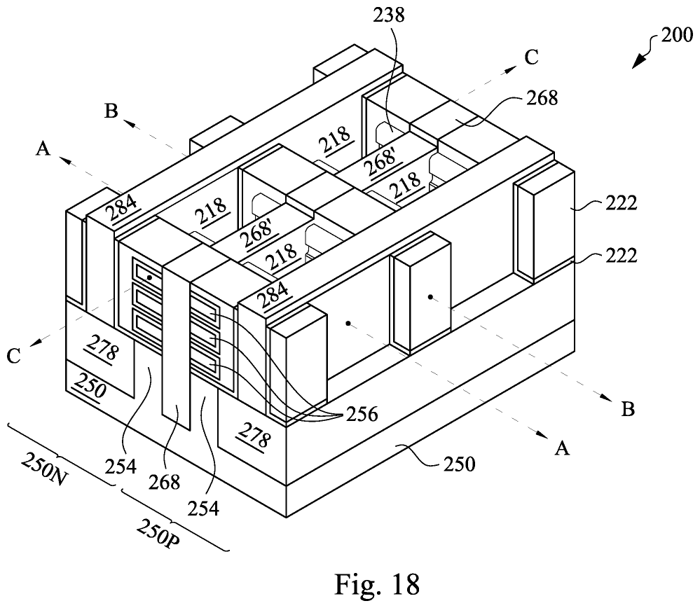

FIG. 18 schematically illustrates an example of simplified semiconductor device 200 in accordance with some embodiments. FIG. 18 is a cutaway three-dimensional view, where some features of the semiconductor device 200 are omitted for illustration clarity. In the illustrated embodiment, the semiconductor device 200 includes forksheet FETs. The semiconductor device 200 may also be nanosheet field-effect transistors (NSFETs), nanowire field-effect transistors (NWFETs), gate-all-around field-effect transistors (GAAFETs), or the like.

The semiconductor device 200 may include semiconductor layers 256 over a substrate 250, such as over fins 254 extending from the substrate 250. The semiconductor layers 256 are semiconductor layers that act as channel regions for the semiconductor device 200. Isolation regions 278, such as shallow trench isolation (STI) regions, are disposed over the substrate 250 and adjacent to the semiconductor fins 254.

Gate structures 220 are wrapped around the semiconductor layers 256 and are disposed over the semiconductor fins 254. The gate structures 220 include gate dielectric layers 222 and gate electrodes 224. The gate dielectric layers 222 are along top surfaces, sidewalls, and bottom surfaces of the semiconductor layers 256 and may extend along sidewalls and/or over top surfaces of the semiconductor fins 254. The gate electrodes 224 are on the gate dielectric layers 222. Epitaxial source/drain regions 216 are disposed on opposite sides of the gate structures 220. In some embodiments, the epitaxial source/drain regions 216 are similar to the epitaxial source/drain regions 38 of the semiconductor device 10 having a central cavity 218. The central cavity 218 may be filled with a sacrificial source/drain region and then replaced with a source/drain contact feature.

The substrate 250 has a n-type region 250N and a p-type region 250P. The n-type region 250N includes n-type devices, such as NMOS transistors, e.g., n-type semiconductor device, and the p-type region 250P includes p-type devices, such as PMOS transistors, e.g., p-type semiconductor device. In the illustrated embodiment, the semiconductor device 10 are forksheet FETs. In forksheet FETs, both n-type devices and p-type devices are integrated in a same forksheet structure. A dielectric wall 68 separates the semiconductor fin 254, the semiconductor layers 256 and the epitaxial source/drain regions 216 for a n-type device from the semiconductor fin 254, the semiconductor layers 256 and the epitaxial source/drain regions 216 for a p-type device. In some embodiments, the dielectric wall 268 is formed along the center line. During etch back of the semiconductor fins 254, the dielectric wall 268′ between the gate structures 220 may suffer some loss of height and becomes lower than the dielectric wall 268 across the gate structures 220. Conventionally, the loss height of the dielectric wall 268′ may result source/drain regions on the opposite side to touch. Because growth of the source/drain regions 216 according to the present disclosure terminates before the source/drain cavity is filled, the source/drain regions 216 on opposite sides of the dielectric wall 268 is much less likely to connect and cause defects.

The gate structures 220 extend along three sides of each semiconductor layer 256. Forksheet FETs allow n-type devices and p-type devices to be formed close to one another, and allow the gate structures 220 for the devices to be physically and electrically coupled to one another, thereby reducing the amount of gate contacts used in a CMOS process. Dielectric fins 284 are formed over the isolation regions 278 at cell boundaries, separating adjacent forksheet FETs.

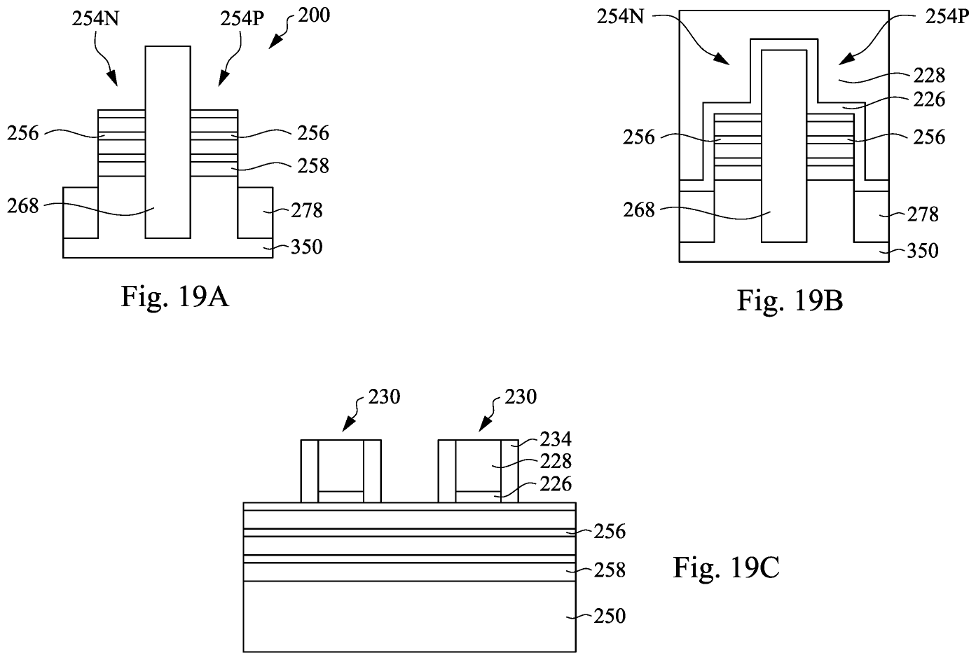

FIGS. 19A-19C, 20A-20C, 21A-21C, 22A-22C, 23A-23C, and 24A-24C schematically illustrate various stages of manufacturing the semiconductor device 200 according to embodiments of the present disclosure. FIGS. 19A-24A are schematic sectional view of the semiconductor device 200 along the A-A line in FIG. 18. FIGS. 19B-24B are schematic sectional view of the semiconductor device 200 along the B-B line in FIG. 18. FIGS. 19C-24C are schematic sectional view of the semiconductor device 200 along the C-C line in FIG. 18.

In FIGS. 19A-19C, the fin structures 254N, 254P are formed on the substrate 250. The fin structure 254N, 254P includes multiple semiconductor layers 256, 258. The dielectric wall 268 are in a gap between the fin structures 254N and 254P. Sacrificial gate structures 230 are formed over the fin structures 254N, 254P, and the dielectric wall 268. The sacrificial gate structure 230 may include a sacrificial gate dielectric layer 226, and the sacrificial gate electrode layer 228. Sidewall spacers 234 are formed on sidewall of the sacrificial gate structures 230.

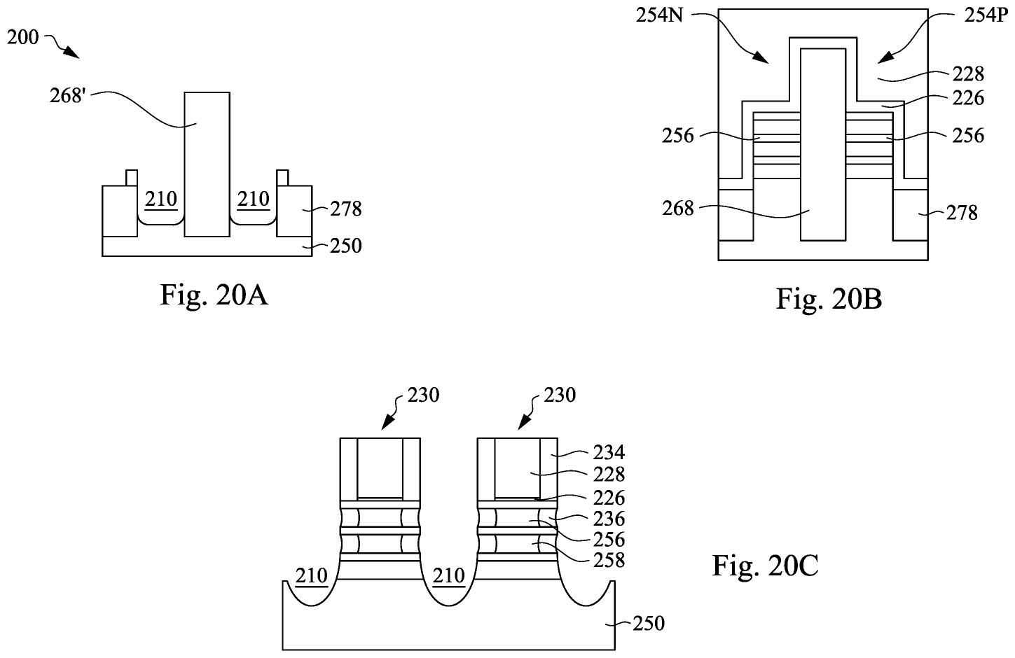

In FIG. 20A-20C, source/drain openings 210 and inner spacers 236 are forms. The exposed fin structure 254N, 254P not covered by the sacrificial gate structures 230 are etched to expose well portions of the fin structure 254N, 254P and form source/drain openings 210, in which source/drain regions are subsequently formed. After recess etch of the fin structure 254N, 254P, the inner spacers 236 are formed. During this operation, the dielectric wall 268′ between the sacrificial gate structures 230, shown in FIG. 20A, suffers some height loss and is lower than the dielectric walls 268 under the sacrificial gate structures 230, shown in FIG. 20B.

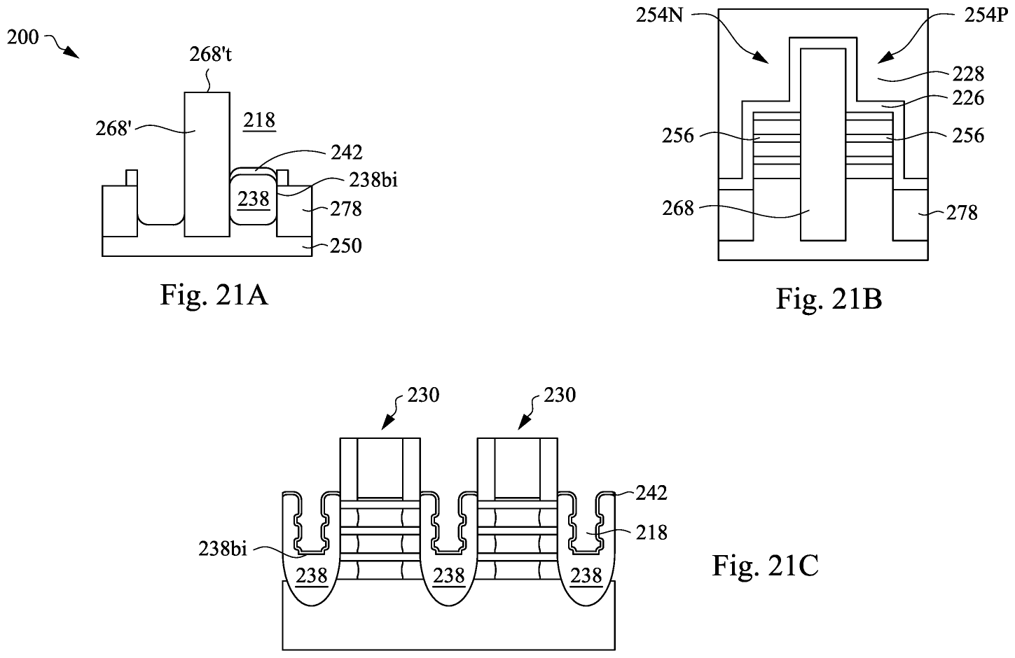

In FIGS. 21A-21C, the epitaxial source/drain regions 238 and an optional etch stop layer 242 are formed. The epitaxial source/drain regions 238 is substantially similar to the epitaxial source/drain regions 38 of the semiconductor device 10, and may be formed according to process described in operation 108. Similar to the epitaxial source/drain region 38, the epitaxial source/drain region 238 also has a concave inner profile and defining a central cavity 218 therein. As shown in FIG. 21A, a center portion of the epitaxial source/drain region 238 terminates at a bottom surface 238bi which is well below a top surface 268′t of the dielectric wall 268′. Therefore, the epitaxial source/drain region 238 is very unlikely to grow over the top surface 268′t of the dielectric wall 268′. The optional etch stop layer 242 is formed over the source/drain region 238. The optional etch stop layer 242 may be similar to the optional etch stop layer 42 of in the semiconductor device 10 and may be formed using the process described in the operation 110.

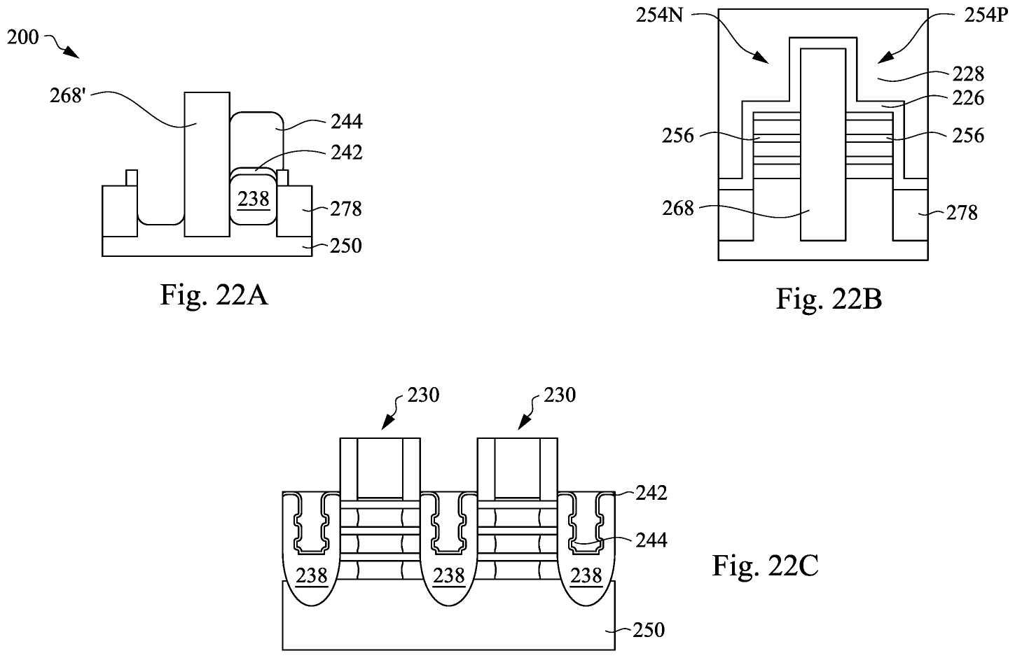

In FIGS. 22A-22C, a sacrificial source/drain region 244 may be deposited in the central cavity 218 and cover the source/drain region 238 and the etch stop layer 242 if present. The sacrificial source/drain region 244 may be similar to the sacrificial source/drain region 44 of in the semiconductor device 10 and may be formed using the process described in the operation 112.

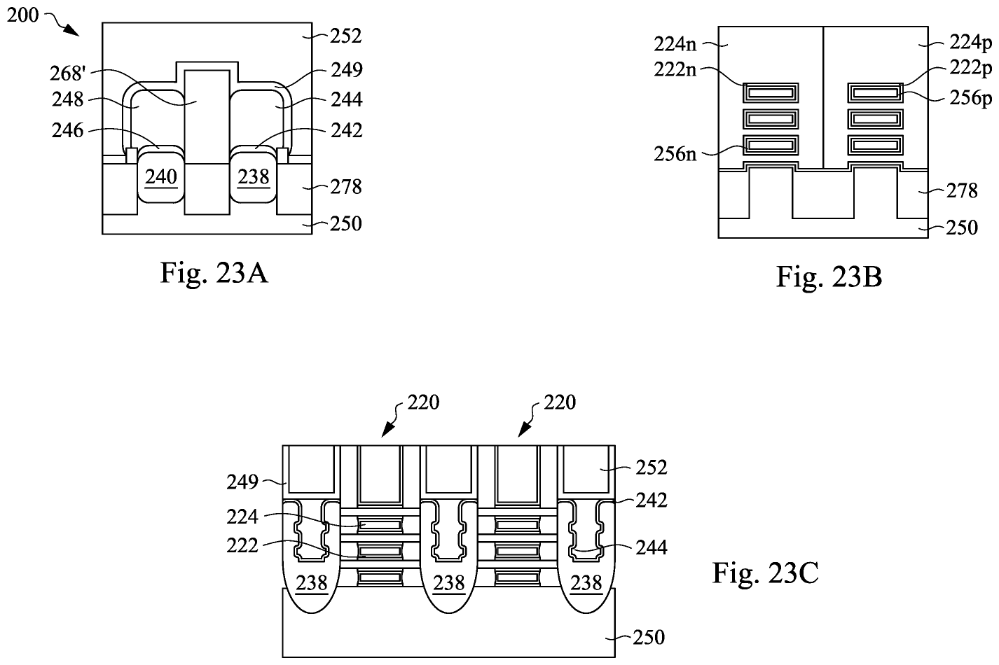

In FIGS. 23A-23C, source/drain regions 240, an optional etch stop layer 246, and a sacrificial source/drain region 248 are formed for the n-type device. As shown in FIG. 23A, the dielectric wall 268′ effectively separate the source/rain regions 238 and the source/drain regions 240. An CESL layer 249 and an ILD layer 252 are then deposited. Replacement gate process sequence is then performed to for the gate structures 220, which includes the gate dielectric layer 222 and the gate electrode 224 are then formed.

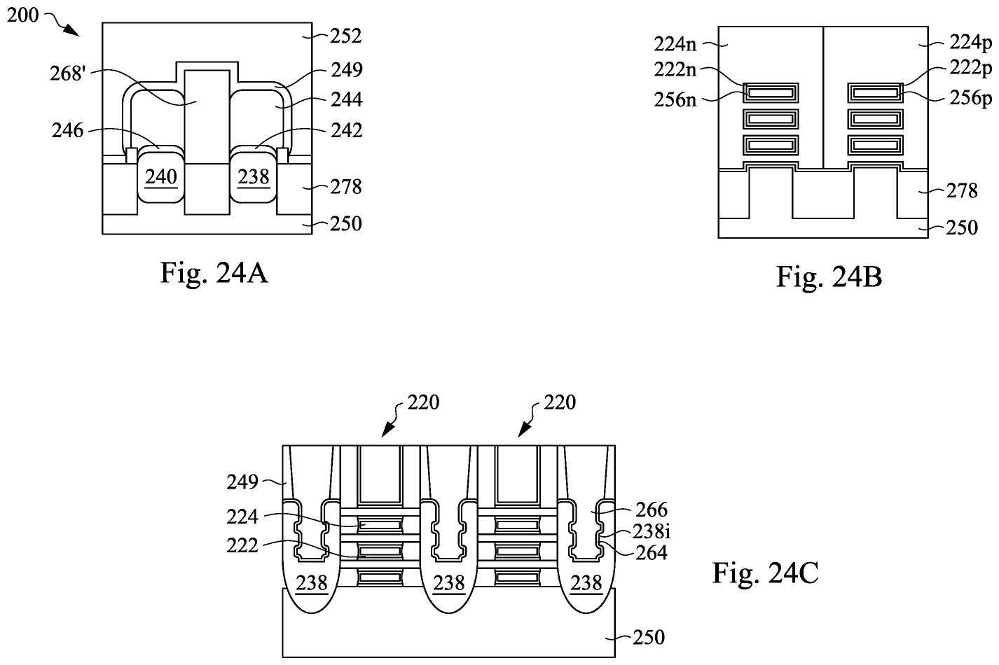

In FIG. 24A-24C, source/drain contact features 266 are formed by patterning the ILD layer 252, removing the sacrificial source/drain regions 244 and 246, and depositing a silicide layer 264, and filling the cavity in the source/drain regions 238, 240. The source/drain contact features 266 are substantially similar to the source/drain contact features 66 in the semiconductor device 10, and may be performed with the process described in operations 118-125.

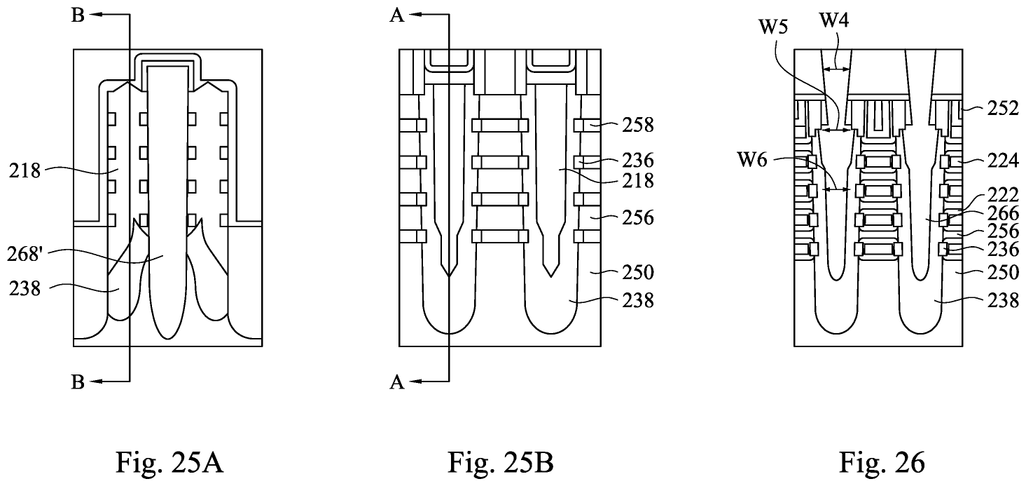

FIGS. 25A-25B, and 26 are cross-sectional views of simulations results forksheet structure according to embodiments of the present disclosure. FIGS. 25A-26B schematically demonstrate an example of the source/drain region 238. FIG. 26 schematically demonstrates the source/drain contact features 266 which is embedded in the source/drain regions 238, with a kinky profile, and reaches the lower most semiconductor layer 256. As shown in FIG. 26, the source/drain contact 266 has a ILD portion disposed through the ILD layer 252, and a core portion disposed below the ILD layer 252. The ILD portion of the source/drain contact 266 has a width W4. The core portion disposed above the source/drain feature 238 has a width W5. The core portion disposed in the source/drain feature 238 has a width W5. The width W4 is narrower than the width W5. The width W6 is narrower than W5. In some embodiments, the width W6 is in a range between about 8 nm and 12 nm.

The source/drain region and source/drain contact feature reduce contact resistance and improve performance of ultra-scaled transistor architectures. The core portion of the contact features wrapped by the source/drain region ensures that bottom channels can be fully accessed due to the largely mitigated current crowding effect, enabling ring oscillator performance gain scales with the sheet numbers. Embodiments also provide relief of high resistance caused by defects and voids in the source/drain regions or source/drain contacts. Embodiments of the present disclosure may also reduce contact resistance for forksheet transistors.

Some embodiments provide a semiconductor device, comprising: an epitaxial source/drain region, wherein the epitaxial source/drain region has an inner profile, and the inner profile includes two or more valley sections alternatively connected between two or more mountain sections; two or more channel layers in contact with the epitaxial source/drain region, wherein the two or more channel layers are vertically stacked, and the two or more channel layers correspond to the two or more mountain sections in the inner profile; and a source/drain contact feature disposed in and on the epitaxial source/drain region, wherein the source/drain contact feature has an outer profile matching the inner profile of the epitaxial source/drain region.

Some embodiments provide a semiconductor device, comprising: a first source/drain region, wherein the first source/drain region has a first inner profile; a second source/drain region disposed adjacent the first source/drain region, wherein the second source/drain region has a second inner profile; a forksheet structure comprising: a plurality of first channels in contact with the first source/drain region; a plurality of second channels in contact with the second source/drain region; a dielectric wall disposed between the plurality of first channel and the plurality of second channels; a first source/drain contact feature disposed over the first inner profile of the first source/drain region, wherein the first source/drain contact feature extends from a first vertical level above a topmost of the plurality of first channels to a second vertical level below a lower most of the plurality of first channels; and a second source/drain contact feature disposed in the second cavity of the second source/drain region.

Some embodiments provide a method, comprising: forming a first fin structure along a first direction; forming a sacrificial gate structure along a second direction and across the first fin structure; etching back the first fin structure to form source/drain openings on opposing sides of the sacrificial gate structure; forming epitaxial source/drain regions in the source/drain openings, wherein each of the epitaxial source/drain regions includes a central cavity; filling the central cavity with a sacrificial source/drain region; depositing a CESL (contact etch stop layer) over the sacrificial source/drain region; depositing an ILD (interlayer dielectric) layer over the CESL layer; forming a source/drain contact opening through the ILD layer and CESL layer to expose the sacrificial source/drain region; removing the sacrificial source/drain region to form a source/drain cavity; and filling the source/drain cavity to form a source/drain contact feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
an epitaxial source/drain region, wherein the epitaxial source/drain region has an inner profile, and the inner profile includes two or more valley sections alternatively connected between two or more mountain sections;
two or more channel layers in contact with the epitaxial source/drain region, wherein the two or more channel layers are vertically stacked, and the two or more channel layers correspond to the two or more mountain sections in the inner profile; and
a source/drain contact feature disposed in and on the epitaxial source/drain region, wherein the source/drain contact feature has an outer profile matching the inner profile of the epitaxial source/drain region.

2. The semiconductor device of claim 1, wherein the epitaxial source/drain region comprises a fin portion and two wing portions extending from the fin portion, the inner profile is defined by the two wing portions and the fin portion.

3. The semiconductor device of claim 2, wherein the two or more channel layers extend between a first vertical level and a second vertical level, and the first vertical level is above the second vertical level.

4. The semiconductor device of claim 3, wherein the source/drain contact feature extends between a third vertical level and a fourth vertical level, the third vertical level is above the fourth vertical level, and the second vertical level is above the four vertical level.

5. The semiconductor device of claim 4, wherein the third vertical level is above the first vertical level.

6. The semiconductor device of claim 1, wherein the source/drain contact feature comprises an ILD portion and a core portion, the core portion is deposed in a central cavity of the epitaxial source/drain region defined by the inner profile and including alternatively narrow sections and wide sections.

7. The semiconductor device of claim 6, wherein the epitaxial source/drain region wraps around the core portion of the source/drain contact feature.

8. The semiconductor device of claim 1, further comprising a sacrificial source/drain feature disposed between the source/drain contact feature and a contact etch stop layer.

9. A semiconductor device, comprising:
a first source/drain region, wherein the first source/drain region has a first inner profile;
a second source/drain region disposed adjacent the first source/drain region, wherein the second source/drain region has a second inner profile;
a forksheet structure comprising:
a plurality of first channels in contact with the first source/drain region;
a plurality of second channels in contact with the second source/drain region;
a dielectric wall disposed between the plurality of first channel and the plurality of second channels;
a first source/drain contact feature disposed over the first inner profile of the first source/drain region, wherein the first source/drain contact feature extends from a first vertical level above a topmost of the plurality of first channels to a second vertical level below a lower most of the plurality of first channels; and
a second source/drain contact feature disposed in the second inner profile of the second source/drain region.

10. The semiconductor device of claim 9, wherein the first source/drain contact feature comprises an ILD portion disposed in an ILD layer and a core portion disposed in a first cavity defined by the first inner profile.

11. The semiconductor device of claim 10, wherein the core portion of the first source/drain contact feature has an outer profile matching the first inner profile of the first source/drain region.

12. The semiconductor device of claim 11, wherein the ILD portion has a first width, and the core portion has a second width, and the second width is wider than the first width.

13. The semiconductor device of claim 11, wherein the first inner profile includes a plurality of valley sections alternatively connected between a plurality of mountain sections.

14. The semiconductor device of claim 10, further comprising a sacrificial epitaxial source/drain region disposed around the first source/drain contact feature.

15. A method, comprising:
forming a first fin structure along a first direction;
forming a sacrificial gate structure along a second direction and across the first fin structure;
etching back the first fin structure to form source/drain openings on opposing sides of the sacrificial gate structure;
forming epitaxial source/drain regions in the source/drain openings, wherein each of the epitaxial source/drain regions includes a central cavity;
filling the central cavity with a sacrificial source/drain region;
depositing a CESL (contact etch stop layer) over the sacrificial source/drain region;
depositing an ILD (interlayer dielectric) layer over the CESL layer;
forming a source/drain contact opening through the ILD layer and CESL layer to expose the sacrificial source/drain region;
removing the sacrificial source/drain region to form a source/drain cavity; and
filling the source/drain cavity to form a source/drain contact feature.

16. The method of claim 15, wherein the first fin structure comprises a plurality of vertically stacked semiconductor layers, and forming the epitaxial source/drain regions comprises:
conformally growing a semiconductor layer from end surfaces of the plurality of vertically stacked semiconductor layers in the source/drain openings; and
terminating growth of the semiconductor layer while a bottom surface of the central cavity is below a lower most semiconductor layer.

17. The method of claim 16, further comprising:
forming an etch stop layer on the epitaxial source/drain regions, wherein the sacrificial source/drain region is formed on the etch stop layer.

18. The method of claim 17, further comprising: after removing the sacrificial source/drain regions, forming a silicide layer from the etch stop layer.

19. The method of claim 16, wherein the central cavity is defined by an inner profile, and the inner profile includes a plurality of valley sections alternatively connected between a plurality of mountain sections.

20. The method of claim 19, wherein the plurality of mountain sections correspond to the plurality of vertically stacked semiconductor layers.
